(19) United States
(12) Patent Application Publication
(10) Pub. No.: US 2026/0013211 A1
(43) Pub. Date: Jan. 8, 2026

(54) Semiconductor structure including thin film resistor layer and manufacturing method thereof

(71) Applicant: UNITED MICROELECTRONICS CORP., Hsin-Chu City (TW)

(72) Inventors: Po-Hsun Wang, Tainan City (TW); Shin-Chi Chen, Tainan City (TW); Chin-Chung Wei, Kaohsiung City (TW); Wen-Ling Lan, Tainan City (TW); Hsin-Fu Huang, Tainan City (TW)

(73) Assignee: UNITED MICROELECTRONICS CORP., Hsin-Chu City (TW)

(21) Appl. No.: 18/796,316

(22) Filed: Aug. 7, 2024

(30) Foreign Application Priority Data
Jul. 5, 2024 (CN) 202410898579.1

(51) Int. Cl. H01L 27/06; H01L 21/02; H01L 21/28; H01L 21/8234; H01L 29/49; H01L 29/66; H01L 29/78

(52) U.S. Cl. CPC H10D 84/811; H01L 21/28088; H10D 1/47; H10D 64/667; H01L 21/02255; H10D 30/027; H10D 30/60; H10D 84/014; H10D 84/038

(57) ABSTRACT

The invention provides a semiconductor structure comprising a thin film resistor layer, which comprises a metal gate, wherein the metal gate comprises a titanium nitride layer, a titanium layer and an aluminum layer stacked from bottom to top, wherein the ratio of the thickness of the aluminum layer to the thickness of the titanium layer is greater than 0.66, and a thin film resistor layer is located in a dielectric layer directly above the metal gate, wherein at least a part of the thin film resistor layer and the metal gate are overlapped from a top view. The invention has the function of reducing the probability of copper extrusion in the P-type gate structure and improving the quality of semiconductor devices.

### BACKGROUND OF THE INVENTION

### 1. Field of the Invention

The invention relates to the field of semiconductor manufacturing, in particular to a semiconductor structure containing a thin film resistor layer and a method for reducing the probability of copper extrusion in a P-type gate structure, which has the effect of improving the quality of semiconductor devices.

### 2. Description of the Prior Art

In today's semiconductor industry, metal-oxide-semiconductor field-effect transistors (MOSFET) mostly use polysilicon material to make their gate. However, polysilicon materials still have many disadvantages: compared with most metal materials, polysilicon gates have higher resistance, so the conductivity of polysilicon gates is lower than that of metal wires. In order to make up for this shortcoming, polysilicon gate needs to be treated with metal silicide to reduce contact resistance and Parasitic Resistance (Rp) at the same time, and improve its operating speed to an acceptable range.

With the semiconductor manufacturing trend of replacing the traditional polysilicon gate with metal gate, the passive devices made of polysilicon materials in the past can also be replaced by metal materials. Similar to the semiconductor manufacturing technology experienced by active devices, passive devices such as thin film resistors can be combined with active devices, for example, in the process of transistor manufacturing, various passive devices can be formed by photolithography, etching and other methods.

Take the combination structure of thin film resistor and transistor as an example. As the size of semiconductor is getting smaller and smaller, the distance between various components is getting smaller and smaller. In the case of closely arranged components, if a single component has structural problems, it will also affect other adjacent components, which will easily lead to various electrical problems. It is necessary to pay more attention to the production quality of a single component and study ways to improve its yield, so as to avoid its defects and thus affect the performance of the whole semiconductor device.

### SUMMARY OF THE INVENTION

The invention provides a semiconductor structure comprising a thin film resistor layer, which comprises a metal gate, wherein the metal gate comprises a titanium nitride layer, a titanium layer and an aluminum layer stacked from bottom to top, wherein the ratio of the thickness of the aluminum layer to the thickness of the titanium layer is greater than 0.66, and a thin film resistor layer is located in a dielectric layer directly above the metal gate, wherein at least a part of the thin film resistor layer and the metal gate are overlapped from a top view.

The invention also provides a method for manufacturing a semiconductor structure comprising a thin film resistor layer, which comprises forming a metal gate, wherein the metal gate comprises a titanium nitride layer, a titanium layer and an aluminum layer stacked from bottom to top, wherein the ratio of a thickness of the aluminum layer to a thickness of the titanium layer is greater than 0.66, and forming a thin film resistor layer in a dielectric layer directly above the metal gate, wherein at least a part of the thin film resistor layer and the metal gate are overlapped from a top view.

The invention provides a semiconductor structure comprising a thin film resistor layer and a metal gate and a manufacturing method thereof. The main feature is that the thin film resistor layer is located right above the metal gate under the miniaturization arrangement of elements. Then, because the metal gate may bulge due to copper extrusion during the heating process, the metal gate may be pushed to the thin film resistor layer at the same time, and may even touch the upper first conductor layer, thus affecting the electrical properties. According to the experiment of the applicant, in the current technology, the thickness of the aluminum layer in the metal gate of the P-type transistor is too thin compared with the thickness of the titanium layer below (the aluminum layer is about 40 angstroms, while the titanium layer is about 90 angstroms), so in the heating process, the thickness of the titanium aluminide layer generated by the aluminum layer and the titanium layer accounts for a higher proportion of the thickness of the aluminum layer, and copper atoms doped in the aluminum layer are more likely to be squeezed out, resulting in copper extrusion. In the structure of the present invention, improvement is made based on the above situation, and further, on the premise of not changing the height of the whole metal gate, the thickness of titanium nitride layer as a barrier layer is reduced, while the thickness of aluminum layer is increased, so that the thickness ratio of aluminum layer to titanium layer is higher than 0.66 (that is, the thickness of aluminum layer is increased to 60 angstroms while the thickness of titanium layer is maintained at 90 angstroms). The applicant's experimental results show that this can reduce the probability of copper extrusion on the metal gate of P-type transistors by about 80%, thus contributing to improving the quality and yield of the whole semiconductor device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIGS. 1 to 2 are schematic cross-sectional views of a semiconductor structure including a thin film resistor layer according to an embodiment of the present invention.

FIG. 3 is a partially enlarged sectional view of an N-type gate structure and a P-type gate structure.

FIG. 4 is a schematic cross-sectional view of a P-type gate structure with copper extrusion.

FIG. 5 is a schematic diagram showing the positional relationship between the first conductive layer, the thin film resistor layer and the gate of the transistor from the top view.

FIG. 6 shows a partially enlarged cross-sectional structural diagram of an adjusted N-type gate structure and a P-type gate structure.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

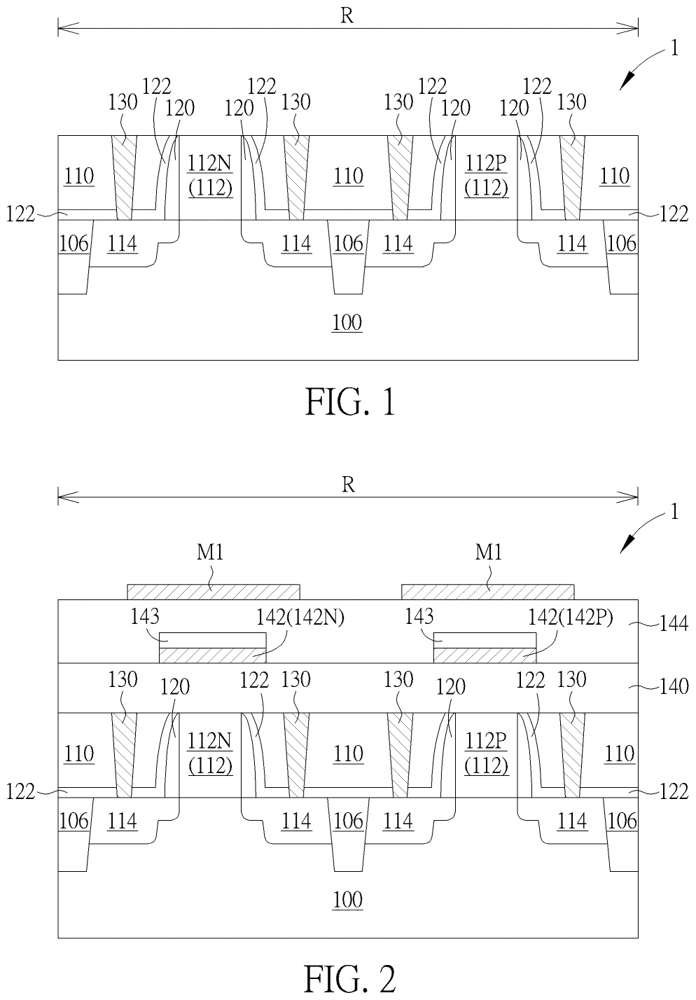

FIGS. 1 to 2 are schematic cross-sectional views of a semiconductor structure. As shown in FIG. 1, the semiconductor structure 1 of the present invention comprises a substrate 100, on which a device region R is defined, and then a plurality of shallow trench isolation, STI 106 for providing different regions with electrical insulation are formed in the substrate 100 of the device region R of the semiconductor structure 1. The substrate 100 can be various semiconductor substrates, such as a silicon substrate, an epitaxial silicon substrate, a silicon germanium substrate, a silicon carbide substrate or a silicon-on-insulator (SOI) substrate.

Referring to FIG. 1, an N-type gate structure 112N and a P-type gate structure 112P are formed in the device region R. The N-type gate structure 112N described here is an N-type metal-oxide semiconductor (NMOS) gate structure, and the P-type gate structure 112P is a P-type metal-oxide semiconductor (PMOS) gate structure. From the process point of view, the N-type gate structure 112N and the P-type gate structure 112P are metal gate structures, for example, metal gates can be formed by a replacement metal gate (RMG) process. For example, two polysilicon gates (not shown) can be formed as dummy gates in the device region R, and after lightly doped drain (LDD), spacer, source/drain, dielectric layer deposition and other processes are completed, gate replacement and contact plug are followed to replace the polysilicon gates with metal gates to form N-type gate structures 112N, respectively. At the same time, a planarization process such as chemical mechanical polishing (CMP) is used to form a flat interlayer dielectric layer 110 on the substrate 100. Then, a plurality of first contacts 130 are formed in the interlayer dielectric layer 110 in the device region R.

In the above embodiment, the N-type gate structure 112N and the P-type gate structure 112P are metal gates, which may include a multi-layer stacked structure. The detailed structure of the stacked structure of the N-type gate structure 112N and the P-type gate structure 112P will be described in the following paragraphs.

The material of the first contact 130 is, for example, aluminum (Al), tungsten (W), copper (Cu), titanium aluminide (TiAl), titanium (Ti), titanium nitride (TiN), tantalum (Ta), tantalum nitride (TaN) or titanium aluminum oxide (TiAlO), etc.

In addition, on both sides of the N-type gate structure 112N and the P-type gate structure 112P, a plurality of spacers 120 with single-layer or multi-layer composite structures made of silicon nitride or silicon oxide and a plurality of doped regions 114 are formed in the substrate 100 on at least one side of the N-type gate structure 112N and the P-type gate structure 112P, and the doped regions 114 include the conventional LDD region (lightly doped drain) and the source/drain region. Moreover, the doped region 114 may further include an epitaxial layer, such as a silicon germanium epitaxial layer or a silicon carbide epitaxial layer, and a metal silicide layer (not shown) may be formed on the surface of the doped region 114, but it is not limited thereto. In addition, a contact etch stop layer (CESL) 122 may be further included between the substrate 100 and the interlayer dielectric layer 110.

Up to this step, as shown in FIG. 1, the device region R of this embodiment includes an N-type gate structure 112N and a P-type gate structure 112P, respectively, in which their respective top surfaces are flush with the top surface of the inter-layer dielectric layer 110, and the top surface of each first contact 130 is also flush with the top surface of the inter-layer dielectric layer 110, and the shape of each first contact 130 is not limited, which may include post contacts or slot contacts.

In addition, in this embodiment, the top surfaces of the N-type gate structure 112N and the P-type gate structure 112P are also flush with each other, which means that the height of the N-type gate structure 112N and the height of the P-type gate structure 112P are equal. Designing the heights of the N-type gate structure 112N and the P-type gate structure 112P to be the same helps to reduce the process complexity of the subsequent semiconductor structure. For example, when forming a contact structure to connect the gate, the contact structure can be formed on the gate with the same height. On the other hand, if the heights of the two gates are different, the etching depth of the contact structure should be specially controlled when forming the contact structure, so as to prevent the contact structure from being connected to the top surface of one gate but not to the other gate.

Then, a dielectric layer and a thin film resistor layer are formed on the N-type gate structure 112N and the P-type gate structure 112P. As shown in FIG. 2, a dielectric layer 140 is formed over the N-type gate structure 112N and the P-type gate structure 112P in the device region R, and then a patterned thin film resistor layer 142 is formed over the N-type gate structure 112N and the P-type gate structure 112P respectively. Here, for convenience of distinction, the thin film resistor layer 142 directly above the N-type gate structure 112N is defined as the thin film resistor layer 142N, and the thin film resistor layer 142 directly above the P-type gate structure 112P is defined as the thin film resistor layer 142P. Then another dielectric layer 144 is formed to cover the thin film resistor layer 142, and a planarization step (such as chemical mechanical polishing) is performed to flatten the surface of the dielectric layer 144. The dielectric layer 140 and the dielectric layer 144 described here are, for example, silicon oxide, silicon nitride, silicon oxynitride or other suitable materials, such as PSG (phosphosilicate glass) and USG (undoped silicate glass). The thin film resistor layer 142 can be made of barrier materials such as titanium nitride or tantalum nitride. In this embodiment, a dielectric layer 140 with a certain thickness is formed first, then a patterned thin film resistor layer 142 is formed, and then a dielectric layer 144 is formed. Therefore, the thin film resistor layer 142 is located between the dielectric layer 140 and the dielectric layer 144.

In some embodiments, as shown in FIG. 2, a mask layer 143 can also be formed above the thin film resistor layer 142, and the material of the mask layer 143 is silicon nitride, for example, but not limited thereto. The mask layer 143 is used to protect the underlying thin film resistor layer 142. For example, when a contact structure is subsequently formed to connect the thin film resistor layer 142, the mask layer 143 can be used as an etching stop layer above the thin film resistor layer 142 to prevent the contact structure from being excessively etched and penetrating through the thin film resistor layer 142. Generally speaking, the mask layer 143 can be formed and stacked on the thin film resistor layer 142 after the thin film resistor layer 142 is formed, and then the mask layer 143 and the thin film resistor layer 142 can be patterned together by an etching step, so the side edges of the mask layer 143 and the thin film resistor layer 142 may be flush from a cross-sectional view, while from a top view (not shown), the areas of the mask layer 143 and the thin film resistor layer 142 may be the same. However, it should be noted that since the mask layer 143 is not a necessary element, the mask layer 143 can also be omitted in other embodiments of the present invention (for example, the mask layer 143 is omitted in the embodiment of FIG. 4 shown later), and this variation is also within the scope of the present invention.

In some semiconductor devices, it is necessary to integrate passive components (such as thin film resistors) with active components (such as transistors). As the size of semiconductor devices is gradually shrinking, the space can be effectively utilized by arranging the thin film resistor layer 142 directly above the transistor. That is to say, there is no need to use other space to accommodate the thin film resistor layer. Next, a first conductive layer M1 is formed above the dielectric layer 144, wherein the material of the first conductive layer M1 is, for example, metal, such as tungsten, cobalt, copper, aluminum, gold, silver, etc. The first conductive layer M1 is used to connect various electronic components below, including transistors, resistors and other electronic components above.

In the above configuration, the thin film resistor layer 142 is inserted between the first conductive layer M1 and the gates of the transistor (the N-type gate structure 112N and the P-type gate structure 112P). Although this configuration can achieve the effect of saving space, there are some hidden dangers, that is, the distance between the first conductive layer M1 and the thin film resistor layer 142 is short, which may affect the electrical properties. The present invention discusses the situation that copper extrusion in the metal gate will affect the thin film resistor layer 142 or even the first wire layer M1, and puts forward corresponding improvement methods. See the following paragraphs for details.

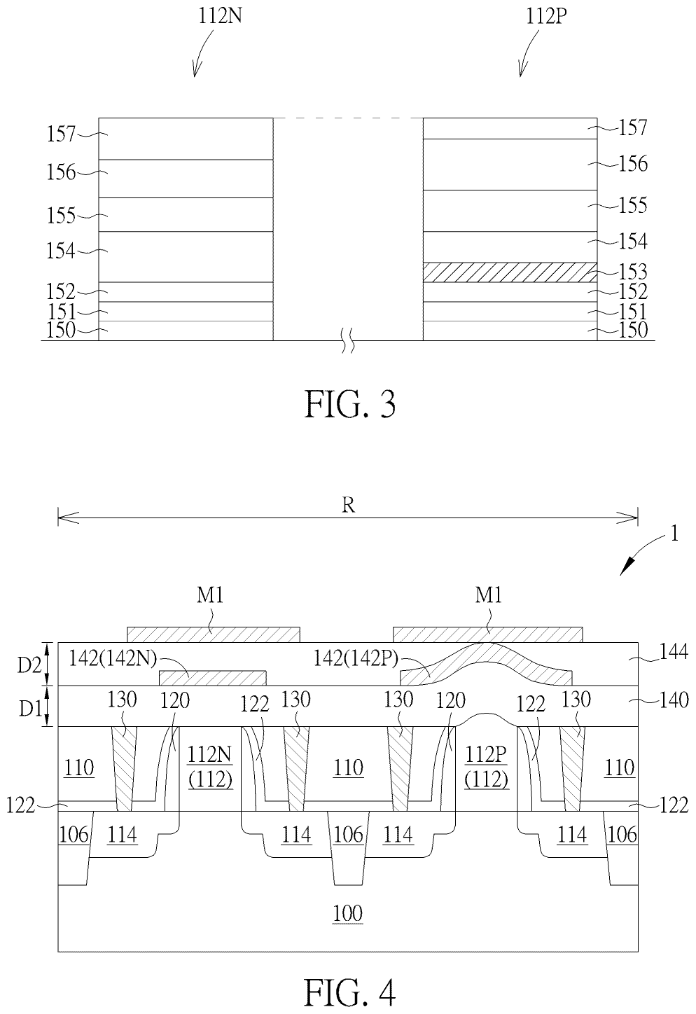

Please refer to FIG. 3, which shows a partially enlarged cross-sectional view of the N-type gate structure and the P-type gate structure. In FIG. 3, the N-type gate structure 112N and the P-type gate structure 112P are represented by a multilayer stacked structure. As shown in FIG. 3, both the N-type gate structure 112N and the P-type gate structure 112P include multilayer stacked structures. The N-type gate structure 112N includes a high-k (high dielectric constant) layer 150, a liner 151, a liner 152, an N-type work function metal layer 154, a barrier layer 155, a titanium layer 156 and an aluminum layer 157 in a bottom-up stacked structure. The material of the high dielectric constant layer 150 can be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta2O₉, SBT), lead zirconate titanate (PbZrxTi₁-xO₃, PZT), barium strontium titanate (BaxSr₁-xTiO₃, BST) or a combination thereof, this embodiment takes hafnium oxide as an example, but is not limited to this. The materials of other material layers are as follows, but are not limited to this: the materials of the liner 151 and the liner 152 contain titanium nitride or titanium oxide, the material of the N-type work function metal layer 154 contains titanium aluminide (TiAl₃), the material of the barrier layer 155 contains titanium nitride (TiN), the material of the titanium layer 156 contains titanium (Ti), and the material of the aluminum layer 157 contains aluminum (Al), but the aluminum layer 157 may be doped with a small amount of copper.

In this embodiment, a small amount of copper atoms are doped in the aluminum layer 157, mainly for the following reasons: 1. Improving the electro migration resistance: pure aluminum is prone to electro migration at high current density, which leads to cavities or fractures in metal lines and affects the reliability of components. Doping a small amount of copper can effectively inhibit electro migration and improve the life of metal wires. 2. Enhance mechanical strength: Doping copper can improve the mechanical strength and hardness of aluminum layer, make it more wear-resistant and corrosive, and thus improve the reliability of components. 3. Improving thermal stability: Doping copper can increase the recrystallization temperature of aluminum layer, making it more stable at high temperature, and it is not easy to cause grain growth or phase transformation, thus ensuring the performance of components. It should be noted that the doping amount of copper is usually very small, generally below 0.5%. Excessive copper doping will reduce the conductivity of aluminum layer, increase the contact resistance, and even lead to increased electro migration.

On the other hand, the P-type gate structure 112P has almost the same structure as the N-type gate structure 112N, but besides the above-mentioned high-k layer 150, the liner 151, the liner 152, the N-type work function metal layer 154, the barrier layer 155, the titanium layer 156 and the aluminum layer 157, a P-type work function metal layer 153 is further included between the liner 152 and the N-type work function metal layer 154. In this embodiment, the P-type work function metal layer 153 contains titanium nitride (TiN), but the present invention is not limited to this.

In this embodiment, in the N-type gate structure 112N, the thickness of the N-type work function metal layer 154 is about 100 angstroms, the thickness of the barrier layer 155 is about 50 angstroms, the thickness of the titanium layer 156 is about 90 angstroms, and the thickness of the aluminum layer 157 is about 80 angstroms. On the other hands, in the P-type gate structure 112P, the thickness of the P-type work function metal layer 153 is about 40 angstroms, the thickness of the N-type work function metal layer 154 is about 100 angstroms, the thickness of the barrier layer 155 is about 50 angstroms, the thickness of the titanium layer 156 is about 90 angstroms, and the thickness of the aluminum layer 157 is about 40 angstroms, respectively. However, the thickness of each material layer is only an example of the present invention, and the present invention is not limited to this. In the present invention, the heights of the N-type gate structure 112N and the P-type gate structure 112P are preferably the same.

In addition, it is worth noting that because the gate structure of this case is to form a groove first, and then fill in the above-mentioned various material layers (such as work function metal layer, barrier layer, metal layer, etc.) in sequence, each material layer will cover the bottom surface and sidewalls of the groove after filling in the groove, so that from the cross-sectional view, each material layer presents a “U” shape. However, in FIG. 3 and the following FIG. 6, for the sake of simplicity, only the stacking relationship of material layers is drawn, but the material layers with U-shaped section are not drawn. However, it can be understood that a material layer with a U-shaped cross section is also within the scope of the present invention.

As mentioned above, the applicant hopes to make the P-type gate structure 112P and the N-type gate structure 112N have the same gate height, so as to facilitate the subsequent process. However, as shown in FIG. 3 above, in the detailed stacked structure, because the P-type gate structure 112P has a P-type work function metal layer 153 more than the N-type gate structure 112N, the thickness of the aluminum layer 157 in the P-type gate structure 112P is lower than that in the N-type gate structure 112N (in this embodiment, the thickness of the aluminum layer 157 in the P-type gate structure 112P is 40 angstroms, and the thickness of the aluminum layer 157 in the N-type gate structure 112N is 80 angstroms, respectively) when the same gate height is required.

However, the applicant found that under such a configuration, in the subsequent heating step, the P-type gate structure 112P is prone to copper extrusion, which further affects the upper thin film resistor layer 142 and even the first conductive layer M1. In more detail, the applicant found that after the completion of the P-type gate structure 112P and the N-type gate structure 112N, a TEOS layer was formed on the P-type gate structure 112P and the N-type gate structure 112N, and then the TEOS layer was oxidized by a heating step to form a dielectric layer 140. In the above heating process, the temperature is raised to above 400 degrees Celsius, and the applicant found that a convex part is easily generated at the top of the P-type gate structure 112P at this time. On the other hand, the applicant also found that the above-mentioned protruding part is easy to occur in the P-type gate structure 112P, but not easy to occur in the N-type gate structure. The phenomenon that the top surface of the above P-type gate structure 112P bulges after heating is called copper extrusion.

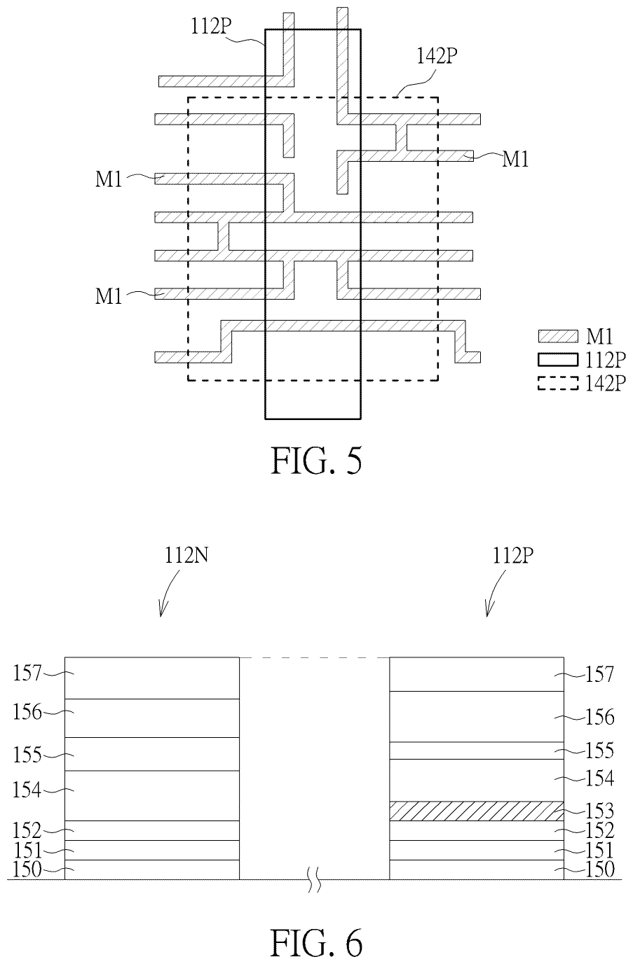

Reference can be made to FIG. 4 and FIG. 5 together. FIG. 4 shows a schematic cross-sectional structure of a P-type gate structure causing copper extrusion, and FIG. 5 shows a schematic diagram of the positional relationship between the first conductor layer, the thin film resistor layer and the gate of the transistor from the top view. As shown in FIG. 4 and FIG. 5, in this embodiment, the first conductive layer M1, the thin film resistor layer 142 and the P-type gate structure 112P partially overlap each other from the top view, so when the subsequent process temperature is higher than 400 degrees Celsius and the vertical distance among the thin film resistor layer 142, the first conductive layer M1 and the P-type gate structure 112P is close, the copper extrusion phenomenon generated by the P-type gate structure 112P will affect the thin film resistor layer 142 and the first conductive layer M1. More specifically, the copper extrusion phenomenon generated by the P-type gate structure 112P may push the upper thin film resistor layer 142 and even the first wire layer M1, so that the thin film resistor layer 142 contacts the first wire layer M1 and short circuit will occur. From FIG. 4, the thickness of the dielectric layer 140 is defined as D1, and the thickness of the dielectric layer 144 is defined as D2. In this embodiment, D1 is about 200 angstroms, while D2 is about 600 angstroms. Therefore, when the distance between elements is close, copper extrusion will affect the electrical properties of semiconductor structures.

According to the applicant's research, it is found that the copper extrusion phenomenon is easy to occur in the P-type gate structure 112P because the thickness of the aluminum layer 157 in the P-type gate structure 112P is lower than that of the titanium layer 156. For the embodiment of FIG. 3, the ratio of the thickness of the aluminum layer 157 (40 angstroms) to the thickness of the titanium layer 156 (90 angstroms) in the P-type gate structure 112P is about 4:9. Since the temperature is raised to over 400° C. during the heating process, a titanium aluminide layer (not shown) is additionally generated between the aluminum layer 157 and the titanium layer 156, which means that the titanium aluminide layer is formed below the aluminum layer 157. In the process of forming this titanium aluminide layer, the aluminum atoms in the aluminum layer 157 will be grabbed, so the aluminum atoms in the aluminum layer 157 will move downward. As mentioned above, the aluminum layer 157 is also doped with a small amount of copper atoms, so the remaining copper atoms will move upward more easily. When the overall thickness of the aluminum layer 157 is thin, the copper atoms will easily move to the top of the entire aluminum layer 157, and copper extrusion will more easily occur.

Compared with the P-type gate structure 112P, copper extrusion is less likely to occur in the N-type gate structure 112N because the thickness of the aluminum layer 157 in the N-type gate structure 112N is higher than that of the titanium layer 156. For the embodiment of FIG. 3, the ratio of the thickness of the aluminum layer 157 (80 angstroms) to the thickness of the titanium layer 156 (90 angstroms) in the N-type gate structure 112N is about 8:9. Therefore, when the titanium aluminide layer is formed, the thickness of the aluminum layer 157 is thick to prevent the copper atoms from moving upward, so that the copper atoms are not easy to move to the top of the whole aluminum layer 157, and the phenomenon of copper extrusion is less likely to occur. According to the applicant's experimental results, under the same process conditions, the probability of copper extrusion happened in the P-type gate structure 112P is about 50%-55%, while the probability of copper extrusion happened in the N-type gate structure 112N is only about 1%-3%.

Therefore, in summary, when the semiconductor structure meets the following specific conditions, the P-type gate structure is prone to copper extrusion and affects the quality of semiconductor devices. These conditions include: 1. From the top view, the first conductive layer M1, the thin film resistor layer 142 and the P-type gate structure 112P partially overlap with each other (as shown in FIG. 4-FIG. 5); 2. After forming the P-type gate structure 112P, the temperature of the subsequent process is increased to above 400° C.; 3. The distance between the first conductive layer M1, the thin film resistor layer 142 and the P-type gate structure 112P in the vertical direction is close enough (within about 700 angstroms).

In order to reduce the occurrence probability of copper extrusion under the above conditions, in the method provided by the present invention, when the above conditions are met, the composition ratio of the gate structure in the transistor will be adjusted, especially the thickness relationship among the aluminum layer 157, the titanium layer 156 and the barrier layer 155 in the P-type gate structure 112P, so as to reduce the occurrence probability of copper extrusion. In more detail, please refer to FIG. 6, which shows a partially enlarged cross-sectional structural diagram of an improved N-type gate structure and P-type gate structure. Referring to FIG. 6 and the aforementioned FIG. 3, in this embodiment, the thickness ratio between the aluminum layer 157, the titanium layer 156 and the barrier layer 155 of the P-type gate structure 112P is adjusted, especially the thickness of the aluminum layer 157 is increased from about 40 angstroms to 60 angstroms, while the thickness of the titanium layer 156 is maintained at about 90 angstroms, while the thickness of the barrier layer 155 is reduced from 50 angstroms to about 30 angstroms. The reason for this adjustment is that in the gate stack structure, the thicknesses of other layers, such as the N-type work function metal layer 154 and the P-type work function metal layer 153, are highly related to the electrical properties of the gate structure, so if the thicknesses of these layers are changed, other fabrication parameters need to be adjusted. However, the function of the barrier layer 155 in the gate structure is to prevent atomic diffusion, so reducing the thickness of the barrier layer 155 has little effect on the electrical properties of the whole gate stack structure. After adjustment, according to the applicant's experimental observation, the probability of copper extrusion of the P-type gate structure 112P is reduced from about 55% to about 12%, that is to say, compared with the original structure shown in FIG. 3, the probability of copper extrusion is greatly reduced by about 80%. Therefore, the electrical problems caused by copper extrusion can be effectively solved. In addition, it is worth noting that the heights of the P-type gate structure 112P and the N-type gate structure 112N in FIG. 6 are still the same, that is to say, the height of the metal gate is not changed.

Based on the above description and drawings, the present invention provides a semiconductor structure including a thin film resistor layer, which includes a metal gate (especially the P-type gate structure 112P of FIG. 6), wherein the metal gate 112P includes a titanium nitride layer (the barrier layer 155), a titanium layer 156 and an aluminum layer 157 stacked from bottom to top, wherein the ratio of the thickness of the aluminum layer 157 to the thickness of the titanium layer 156 is greater than 0.66. (For example, the thickness of the aluminum layer 157 is more than 60 angstroms, while the thickness of the titanium layer 156 is about 90 angstroms), and a thin film resistor layer 142 is located in a dielectric layer directly above the metal gate 112P, wherein at least a part of the thin film resistor layer 142P overlaps with the metal gate 112P when viewed from a top view.

In some embodiments of the present invention, a first conductive layer M1 is further included, which is located in the dielectric layer 140 on the thin film resistor layer 142P, and at least a part of the first conductive layer M1, the thin film resistor layer 142P and the metal gate 112P are overlapped from the top view.

In some embodiments of the present invention, the aluminum layer 157 of the metal gate 112P is doped with copper.

In some embodiments of the present invention, the ratio of the thickness of titanium nitride layer 155 to the thickness of titanium layer 156 is less than 0.33 (please refer to the embodiment shown in FIG. 6, the adjusted barrier layer 155 is about 30 angstroms, while the thickness of titanium layer 156 is maintained at about 90 angstroms).

In some embodiments of the present invention, the metal gate is a P-type metal gate, which includes an N-type work function metal layer 154 and a P-type work function metal layer 153 under the titanium nitride layer 155.

In some embodiments of the present invention, the material of the N-type work function metal layer 154 comprises titanium aluminide (TiAl₃), and the material of the P-type work function metal layer 153 comprises TiN.

In some embodiments of the present invention, another titanium aluminide layer is included, which is located between the aluminum layer 157 and the titanium layer 156 in the metal gate 112P (as mentioned in the previous paragraph, when the temperature is raised to over 400 degrees Celsius during the heating process, the titanium aluminide layer will react between the aluminum layer 157 and the titanium layer 156).

In some embodiments of the present invention, an overall height of the metal gate is less than 360 angstroms.

The present invention also provides a method for manufacturing a semiconductor structure including a thin film resistor layer, which includes forming a metal gate (especially the P-type gate structure 112P of FIG. 6), wherein the metal gate 112P includes a titanium nitride layer (barrier layer 155), a titanium layer 156 and an aluminum layer 157 stacked from bottom to top, wherein the ratio of the thickness of the aluminum layer 157 to the thickness of the titanium layer is greater than 0.66, and forming a thin film resistor layer. In a dielectric layer 140 directly above the metal gate 112P, at least a part of the thin film resistor layer 142P and the metal gate 112P overlap each other when viewed from a top view.

In some embodiments of the present invention, the method of forming the dielectric layer 140 includes forming a TEOS layer on the metal gate 112P after the metal gate 112P is formed, and performing a heating step to convert the TEOS layer into the dielectric layer 140.

In some embodiments of the present invention, the temperature of the heating step is higher than 400 degrees Celsius.

In some embodiments of the present invention, a mask layer 143 is further included to cover the thin film resistor layer 142P, wherein an area of the mask layer 143 is equal to an area of the thin film resistor layer 142P.

The invention provides a semiconductor structure comprising a thin film resistor layer and a metal gate and a manufacturing method thereof. The main feature is that the thin film resistor layer is located right above the metal gate under the miniaturization arrangement of elements. Then, because the metal gate may bulge due to copper extrusion during the heating process, the metal gate may be pushed to the thin film resistor layer at the same time, and may even touch the upper first conductor layer, thus affecting the electrical properties. According to the experiment of the applicant, in the current technology, the thickness of the aluminum layer in the metal gate of the P-type transistor is too thin compared with the thickness of the titanium layer below (the aluminum layer is about 40 angstroms, while the titanium layer is about 90 angstroms), so in the heating process, the thickness of the titanium aluminide layer generated by the aluminum layer and the titanium layer accounts for a higher proportion of the thickness of the aluminum layer, and copper atoms doped in the aluminum layer are more likely to be squeezed out, resulting in copper extrusion. In the structure of the present invention, improvement is made based on the above situation, and further, on the premise of not changing the height of the whole metal gate, the thickness of titanium nitride layer as a barrier layer is reduced, while the thickness of aluminum layer is increased, so that the thickness ratio of aluminum layer to titanium layer is higher than 0.66 (that is, the thickness of aluminum layer is increased to 60 angstroms while the thickness of titanium layer is maintained at 90 angstroms). The applicant's experimental results show that this can reduce the probability of copper extrusion on the metal gate of P-type transistors by about 80%, thus contributing to improving the quality and yield of the whole semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure with a thin film resistor layer, comprising:
a metal gate including a titanium nitride layer, a titanium layer and an aluminum layer stacked from bottom to top, wherein the ratio of a thickness of the aluminum layer to a thickness of the titanium layer is greater than 0.66; and
a thin film resistor layer located in a dielectric layer directly above the metal gate, wherein at least a part of the thin film resistor layer and the metal gate overlap each other when viewed from a top view.

2. The semiconductor structure semiconductor structure with a thin film resistor layer according to claim 1, further comprising a first conductive layer located in the dielectric layer on the thin film resistor layer, and at least a part of the first conductive layer, the thin film resistor layer and the metal gate are overlapped from the top view.

3. The semiconductor structure semiconductor structure with a thin film resistor layer according to claim 1, wherein the aluminum layer of the metal gate is doped with copper.

4. The semiconductor structure semiconductor structure with a thin film resistor layer according to claim 1, wherein the ratio of a thickness of the titanium nitride layer to a thickness of the titanium layer is less than 0.33.

5. The semiconductor structure semiconductor structure with a thin film resistor layer according to claim 1, wherein the metal gate is a P-type metal gate, which comprises an N-type work function metal layer and a P-type work function metal layer under the titanium nitride layer.

6. The semiconductor structure semiconductor structure with a thin film resistor layer according to claim 1, wherein the material of the N-type work function metal layer comprises titanium aluminide (TiAl₃) and the material of the P-type work function metal layer comprises TiN.

7. The semiconductor structure semiconductor structure with a thin film resistor layer according to claim 1, further comprising another titanium aluminide layer located between the aluminum layer and the titanium layer in the metal gate.

8. The semiconductor structure semiconductor structure with a thin film resistor layer according to claim 1, wherein an overall height of the metal gate is less than 360 angstroms.

9. A method for manufacturing a semiconductor structure with a thin film resistor layer, comprising:
forming a metal gate including a titanium nitride layer, a titanium layer and an aluminum layer stacked from bottom to top, wherein the ratio of a thickness of the aluminum layer to a thickness of the titanium layer is greater than 0.66; and
forming a thin film resistor layer in a dielectric layer directly above the metal gate, wherein at least a part of the thin film resistor layer and the metal gate overlap each other from a top view.

10. The method for manufacturing a semiconductor structure semiconductor structure with a thin film resistor layer according to claim 9, further comprising forming a first conductive layer in the dielectric layer on the thin film resistor layer, and at least a part of the first conductive layer, the thin film resistor layer and the metal gate are overlapped from the top view.

11. The method for manufacturing a semiconductor structure semiconductor structure with a thin film resistor layer according to claim 9, wherein the aluminum layer of the metal gate is doped with copper.

12. The method for manufacturing a semiconductor structure semiconductor structure with a thin film resistor layer according to claim 9, wherein the ratio of a thickness of the titanium nitride layer to the thickness of the titanium layer is less than 0.33.

13. The method for manufacturing a semiconductor structure semiconductor structure with a thin film resistor layer according to claim 9, wherein the metal gate is a P-type metal gate, which comprises an N-type work function metal layer and a P-type work function metal layer under the titanium nitride layer.

14. The method for manufacturing a semiconductor structure semiconductor structure with a thin film resistor layer according to claim 9, wherein the material of the N-type work function metal layer comprises titanium aluminide (TiAl₃) and the material of the P-type work function metal layer comprises TiN.

15. The method for manufacturing a semiconductor structure semiconductor structure with a thin film resistor layer according to claim 9, further comprising forming another titanium aluminide layer between the aluminum layer and the titanium layer in the metal gate.

16. The method for manufacturing a semiconductor structure semiconductor structure with a thin film resistor layer according to claim 9, wherein a total height of the metal gate is less than 360 angstroms.

17. The method for manufacturing a semiconductor structure semiconductor structure with a thin film resistor layer according to claim 9, wherein the method of forming the dielectric layer comprises:
forming a tetraethyl silicate (TEOS) layer on the metal gate after the metal gate is formed; and
performing a heating step to convert the tetraethyl silicate layer into the dielectric layer.

18. The method for manufacturing a semiconductor structure semiconductor structure with a thin film resistor layer according to claim 17, wherein the temperature of the heating step is higher than 400 degrees Celsius.

19. The method for manufacturing a semiconductor structure semiconductor structure with a thin film resistor layer according to claim 9, further comprising forming a mask layer covering the thin film resistor layer, wherein an area of the mask layer is equal to an area of the thin film resistor layer.
